(19) United States
(12) Patent Application Publication
(10) Pub. No.: US 2016/0260674 A1
(43) Pub. Date: Sep. 8, 2016

(54) REMOVAL OF INTEGRATED CIRCUIT CHIPS FROM A WAFER

(71) Applicant: GLOBALFOUNDRIES Inc., Grand Cayman (KY)

(72) Inventors: Bradley P. Jones, Pleasant Valley, NY (US); Thomas W. Dyer, Pleasant Valley, NY (US)

(21) Appl. No.: 14/636,679

(22) Filed: Mar. 3, 2015

(51) Int. Cl. H01L 23/00; H01L 23/48; H01L 21/82; H01L 23/544

(52) U.S. Cl. CPC H01L 23/562; H01L 23/544; H01L 23/481; H01L 21/82; H01L 2223/5446

(57) ABSTRACT

Upon a wafer, integrated circuit (IC) chips are separated by a kerf that includes a through kerf via (TKV). The chips are removed from the wafer and separated from each other by removing the TKV. The TKV may be formed simultaneous or subsequent to formation of a through via (TSV) within an active inner region of each IC chip. The TKV reduces wasted area of the wafer allowing for more IC chips to be included thereupon. Further, the TKV allows for IC chips included in the wafer to differ in perimeter geometry.

### FIELD

Embodiments of invention generally relate to semiconductor devices, design structures for designing a semiconductor device, and semiconductor device fabrication methods. More particularly, embodiments relate to the removal of integrated circuit (IC) chips from a wafer.

### BACKGROUND

Numerous integrated circuits are typically manufactured on a single semiconductor wafer. The semiconductor wafer comprises semiconductor chips whereupon the integrated circuits are located. Kerfs or scribe lines separate the chips. The individual chips are typically diced by sawing the wafer along the kerf. The individual chips are then typically packaged, either separately or in a multi-chip module.

Conventional dicing saws are about 62 microns which resulting in a minimum kerf width of about 85 microns between neighboring chips to allow for misalignment of the saw blade. This is wasted area that reduces the number of product IC chips that can fit on a wafer. Further, conventional dicing generally requires cutting along straight lines which results in most IC chips being rectangular and of similar size. In applications where IC chips differ in size, the dicing may destroys or sacrifices some IC chips to obtain a particular IC chip.

During chip dicing operations, cracks form that can propagate into active areas of the IC chip, causing fails. Therefore, crack stop layers have been incorporated into the perimeter of IC chips to prevent the cracks from propagating into the IC chip. Cracks generally propagate through the BEOL (back end of line) dielectrics which are generally brittle materials, such as silicon oxide. Crack stops are generally built around the perimeter of each IC chip, the depth of these structures being limited to the depth of the IC chip device layers. Crack stops can be formed during wafer processing as part of the pattern or during wafer finishing using a laser to create a partial depth groove. Despite use of crack stops, cracks still find their way under and/or through crack stops and significantly impact IC chip yield and reliability. When crack stops are utilized, the minimum width between IC chips is approximately 125 microns, further limiting the number of product IC chips that can fit on the wafer.

### SUMMARY

In an embodiment of the present invention, a semiconductor device includes an active inner region and a kerf region at the perimeter of the active inner region. The active inner region includes a semiconductor substrate, an integrated circuit (IC) device layer formed upon the semiconductor substrate, and a wiring layer formed upon the IC device layer. The IC device layer includes an IC device and the wiring layer includes wiring making electrical contact with the integrated circuit device. The kerf region includes a through kerf via (TKV) extending through the kerf region.

In another embodiment of the present invention, a wafer includes a plurality of chips separated by a kerf comprising the TKV. Each chip includes an active inner region that includes the semiconductor substrate, the IC device layer formed upon the semiconductor substrate, and the wiring layer formed upon the IC device layer.

In another embodiment of the present invention, a semiconductor structure fabrication method includes forming a semiconductor device upon or within a substrate of a first IC chip separated from a second IC chip by a kerf region, forming a TSV extending through the substrate, forming a TKV extending through the kerf region, and separating the first IC chip from the second IC chip by removing the TKV.

These and other embodiments, features, aspects, and advantages will become better understood with reference to the following description, appended claims, and accompanying drawings.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 depicts a wafer, in accordance with various embodiments of the present invention.

FIG. 2 depicts multiple chips diced from the wafer, in accordance with various embodiments of the present invention.

FIG. 3-FIG. 10 depict cross section views of a semiconductor structure at intermediate stages of semiconductor device fabrication, in accordance with various embodiments of the present invention.

FIG. 11 depicts an exemplary semiconductor device fabrication process flow method, in accordance with various embodiments of the present invention.

FIG. 12 depicts a flow diagram of a design process used in semiconductor design, manufacture, and/or test, in accordance with various embodiments of the present invention.

The drawings are not necessarily to scale. The drawings are merely schematic representations, not intended to portray specific parameters of the invention. The drawings are intended to depict only exemplary embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. These exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

Embodiments relate to the removal of integrated circuit (IC) chips from a wafer. In particular, the wafer may include various IC chips separated by a kerf that includes a through kerf via (TKV). The chips are removed from the wafer and separated from each other by removing the TKV. The TKV may be formed simultaneous or subsequent to formation of a through semiconductor via (TSV) within the IC chips. The TKV reduces wasted area of the wafer allowing for more IC chips to be included thereupon. Further, the TKV allows for IC chips to differ in geometry relative to each other.

Embodiments of invention generally relate to semiconductor devices, such as a semiconductor chip (chip). The chip may be planar device and may comprise planar electrodes in parallel planes, made by alternate diffusion of p- and n-type impurities into the semiconductor substrate of the chip. Alternatively, the chip may be a FinFET type device and may comprise a plurality of fins formed from or upon the semiconductor substrate and a gate covering a portion of the fins. The portion of the fins covered by the gate may serve as a channel region of the device. Portions of the fins may also extend out from under the gate and may serve as source and drain regions of the device.

Referring now to the FIGs, wherein like components are labeled with like numerals, exemplary fabrication steps of forming a wafer 5 including multiple chips 10, in accordance with embodiments of the present invention are shown, and will now be described in greater detail below. It should be noted that some of the FIGs depict various cross section views of a portion of chip 10, multiple chips 10, etc. Furthermore, it should be noted that while this description may refer to components of the chip 10 in the singular tense, more than one component may be depicted throughout the figures and within the chip 10. The specific number of components depicted in the figures and the cross section orientation was chosen to best illustrate the various embodiments described herein.

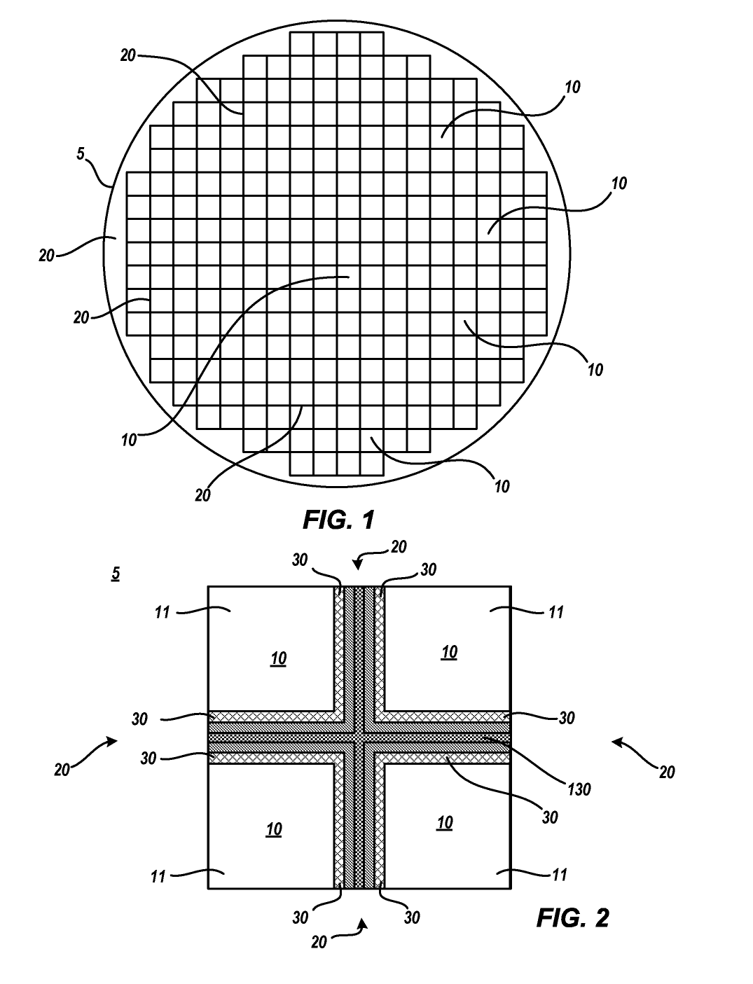

FIG. 1 depicts a wafer 5 comprising a plurality of chips 10 and a plurality of kerfs 20. Each chip 10 may be separated from other chips 10 by kerfs 20. The kerfs 20 may comprise features such e-fuses, alignment structures, fabrication quality, testing, and/or reliability structures, etc. Chips 10 are removed from wafer 5 generally along the scribe or kerf 20.

FIG. 2 depicts multiple chips 10 included in wafer 5. Each chip 10 may comprise an inner active region 11 wherein integrated circuits may be formed and a crack stop region 30 separating the active region 11 from kerf 20. Each inner active region 11 may be enclosed or surrounded by the crack stop region 30 located on the periphery of each chip 10. The crack stop region 30 may consist of similar layers or materials as those in active region 10 (e.g. silicon, etc.) and prevents cracks or delamination from propagating toward the inner active region 11 of the chips 10. Included within kerf 20 is a through-kerf removal via 130 that separates neighboring chips 10. The through-kerf removal via 130 is made from a material that may be removed to separate chips 10. According to embodiments of the present invention, by utilizing through-kerf removal via 130 to remove chips 10 from wafer 5, the width of kerf 20 may be reduced, resulting in a greater number of chips 10 included within wafer 5. According to further embodiments of the present invention, by utilizing through-kerf removal via 130 to remove chips 10 from wafer 5, neighboring chips 10 may be different or have different geometry relative to one another.

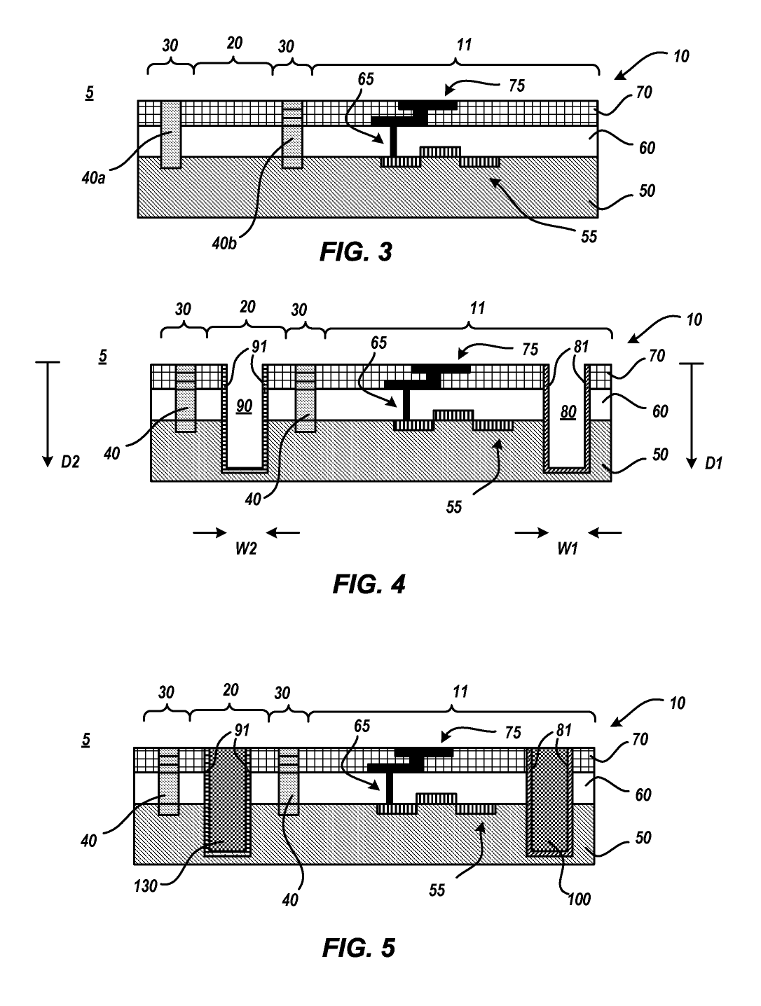

FIG. 3 depicts a cross section view of a semiconductor structure at intermediate stages of semiconductor device fabrication, in accordance with various embodiments of the present invention. For example, at this stage of wafer 5 fabrication, the inner active regions 11 of chips 10 may include a semiconductor substrate 50, a front end of the line (FEOL) layer 60 upon the substrate 50, and BEOL layer 70 upon the FEOL layer 60. In the various embodiments, the semiconductor structure shown in FIG. 3 may be an initial structure that which embodiments of the invention may be realized.

The semiconductor substrate 50 may include, but is not limited to: any semiconducting material such conventional Si-containing materials, Germanium-containing materials, GaAs, InAs and other like semiconductors. Si-containing materials include, but are not limited to: Si, bulk Si, single crystal Si, polycrystalline Si, SiGe, amorphous Si, silicon-on-insulator substrates (SOI), SiGe-on-insulator (SGOI), annealed poly Si, and poly Si line structures. In various embodiments, substrate 50 may be, for example, a layered substrate (e.g. silicon on insulator) or a bulk substrate.

In various embodiments, devices 55 may be formed upon or within the substrate 50. Devices 55 and the process of device 55 fabrication are well known in the art. Devices 55 may be for example, a diode, field effect transistor (FET), metal oxide FET (MOSFET), logic gate, or any suitable combination thereof. Devices 55 also may be components that form a function device such as a gate, fin, source, drain, channel, etc. For clarity, though one device 55 is shown, there are typically numerous devices 55 included within inner active regions 11 of each chip 10. In certain embodiments, devices 55 may be formed within substrate 50. For example, a source and drain may be formed within substrate 50.

The FEOL layer 60 is the layer of chip 10 that generally includes individual devices 55 (e.g. transistors, capacitors, resistors, etc.) patterned in the substrate 50. For example, FinFETs may be implemented in FEOL layer 60 with gate first or gate last FinFET fabrication process techniques. The FEOL layer 60 may include devices 55, one or more dielectric layers, contact 65 to electrically connect device 55 to wiring 75. The BEOL layer 70 is the layer of chip 10 including wiring 75 formed by known wiring 75 fabrication techniques. The BEOL layer 70 may further include one or more dielectric layers and bond sites for chip-to-package connections, etc.

In various embodiments, wafer 5 may further include crack stops 40 for along the perimeter of each chip 10. Crack stop 40 may be formed utilizing known techniques. For example, crack stop 40b may be formed simultaneous to the formation of e.g., devices 55, contact 65, and/or wiring 75. Therefore, each crock stop 40b may include number layers each associated with a particular wiring or device layer. Alternatively, crack stop 40a may be formed by creating a crack stop trench within crack stop region by removing (laser removal, etching, etc.) material within crack stop region 30 and filling the crack stop trench with crack stop material.

FIG. 4 depicts a cross section view of a semiconductor structure at intermediate stages of semiconductor device fabrication, in accordance with various embodiments of the present invention. For example, at this stage of wafer 5 fabrication, a through-silicon hole 80 is formed in active region 11 and a through-silicon trench 90 is formed within kerf region 20. In certain chips 10, a through semiconductor via (TSV) may be utilized. A TSV is a vertical electrical connection via (Vertical Interconnect Access). In embodiments, the TSV passes completely through the semiconductor wafer or die without being connected to wiring 75, contact 65, or device 55. In other embodiments, the TSV 80 is connected to wiring 75, contact 65, or device 55, forming a connection between front side wiring and the back side of the die. TSVs may be used, for example, to allow chip to chip interconnect schemes such as those compatible with three dimensional packaging.

Through-silicon hole 80 and through-silicon trench 90 may be formed, for example, utilizing photolithography and a wet etch, dry etch, or combination. More specifically, a pattern may be produced by applying a masking layer such as a photoresist or photoresist with an underlying hardmask, to the surface to be etched; exposing the photoresist to a pattern of radiation; and then developing the pattern into the photoresist utilizing a resist developer. Once the patterning of the photoresist is completed, the sections covered by the photoresist are protected while the exposed regions are removed using a selective etching process that removes the unprotected regions. In certain embodiments, multiple etches may be employed. For example, a first mask may be used to open the layer(s) over the substrate 50 and open an upper portion of the substrate 50 and a second mask to open a lower portion of the substrate 50.

In various embodiments, through-silicon hole 80 and through-silicon trench 90 may be simultaneously formed. For example, one or more similar etch processes, one or more similar etch masks, one or more similar photoresists, etc. may be employed to form both through-silicon hole 80 and through-silicon trench 90 in a similar trench formation stage. In other embodiments, through-silicon trench 90 may be formed in a stand alone through-silicon trench 90 formation stage. For example, subsequent to the completion of active region 11 formation, through-silicon trench 90 may be formed. In embodiments, through-silicon hole 80 and/or through-silicon trench 90 may be formed before, during or after devices 55, contacts 65, or wiring 75.

In various embodiments, through-silicon hole 80 and through-silicon trench 90 may be formed to have a similar depth. In other embodiments through-silicon hole 80 depth D1 may be less than through-silicon trench 90 depth D2. Similarly, the width W1 of through-silicon hole 80 and the width W2 of through-silicon trench 90 may be similar. However, in various embodiments of the invention, W2 may be larger or smaller than W1. Unless otherwise indicated, generally, hole 80 and trench 90 may be formed by other removal techniques without deviating from the sprit of the embodiments herein claimed.

In embodiments, a liner 91 may be formed within trench 90. Liner 91 may be a dielectric material (e.g. silicon oxide), a metal (e.g. tantalum nitride), or a combination, etc.). Liner 91 may form a perimeter barrier of each chip 10 upon chip 10 separation and aid in the prevention of cracks or delamination propagating into active area 11. Liner 91 may be formed by known deposition techniques. For example, liner 91 may be formed using any of several known methods, for example, thermal or plasma oxidation or nitridation methods, chemical vapor deposition methods, physical vapor deposition methods, etc. A directional etching process may be subsequently utilized to open, reform, etc. trench 90. Similarly, a liner 81 may be formed within hole 80. Liner 81 may be a dielectric material (e.g. silicon oxide, etc.), a metal (e.g. tantalum nitride), or a combination, etc. for electrically isolating TSV 100, shown in FIG. 5, from surrounding active area 11 materials. Liner 81 may be formed by known deposition techniques. For example, liner 81 may be formed using any of several known methods, for example, thermal or plasma oxidation or nitridation methods, chemical vapor deposition methods, physical vapor deposition methods, etc. A directional etching process may be subsequently utilized to open, reform, etc. trench 81. Similar or different etching processes may reform hole 80 and trench 90. Likewise, similar or different formation processes may be utilized to form liner 81 and liner 91 to allow for the materials of liner 81 and liner 91 to be similar/different.

FIG. 5 depicts a cross section view of a semiconductor structure at an intermediate stage of semiconductor device fabrication. At this stage of at this stage of wafer 5 fabrication, TSV 100 and/or through-kerf removal via (TKV) 130 are formed. TSV 100 may be a pillar, stud, etc. and may be fabricated by filling the remaining internal space of the through-silicon hole 80 with a conductive material. TSV 100 may be generally made utilizing other known fabrication techniques.

TKV 130 may be similar to TSV 100 in that it vertically passes completely through a silicon wafer or die and may be formed in similar fabrication stages. For example, TKV 130 passes through the entire kerf region 20. However, TKV 130 may differ from TSV 100 in that it need not make electrical connection from above or below. TKV 130 may be a pillar, stud, elongated pillar, straight wall, shaped wall, curved wall, fabricated by filling the remaining internal space of the through-silicon trench 90 with a TKV material. TKV material may be similar to the material of TSV 100. Generally, TKV material is a material that may be selectively removed relative to other materials of wafer 5 to effectively separate chips 10. For example, during a subsequent selective removal process, the TKV material is removed and the semiconductor substrate 50 material, FEOL layer 60 material, and BEOL layer 70 material is retained. In embodiments, where a TKV liner 91 is utilized, the TKV material is removed and the TKV liner material 91, semiconductor substrate 50 material, FEOL layer 60 material, and BEOL layer 70 material is retained.

In embodiments, TKV 130 may be fabricated without forming the electrically insulating film on the internal surface of the through-silicon trench 90 but by directly filling the through-silicon trench 90 with a conductive material. In other words, in certain embodiments, TKV 130 need not be electrically isolated from surrounding kerf region 20 material.

In various embodiments, TSV 100 and TKV 130 may be simultaneously formed. For example, one or more similar filling processes, similar fill material, etc. may be employed to form both TSV 100 and TKV 130 in a similar formation stage. In other embodiments, TKV 130 may be formed in a stand alone TKV formation stage. For example, subsequent to the completion of active region 11 formation, TKV 130 may be formed. For example, through-silicon trench 90 may be formed utilizing a laser, etc. in a latter wafer 5 fabrication stage and subsequently filled with TKV material. Unless otherwise indicated, generally, TVK 130 and TSV 100 may be formed known deposition techniques without deviating from the sprit of the embodiments herein claimed. In embodiments where TSV 100 and/or TKV 130 are formed before the last wiring level, additional layers of contacts and/or wiring may be built upon the TSV 100 and or TKV 130, simultaneously to the formation of contacts 65 and/or wiring 75 within inner active region 11.

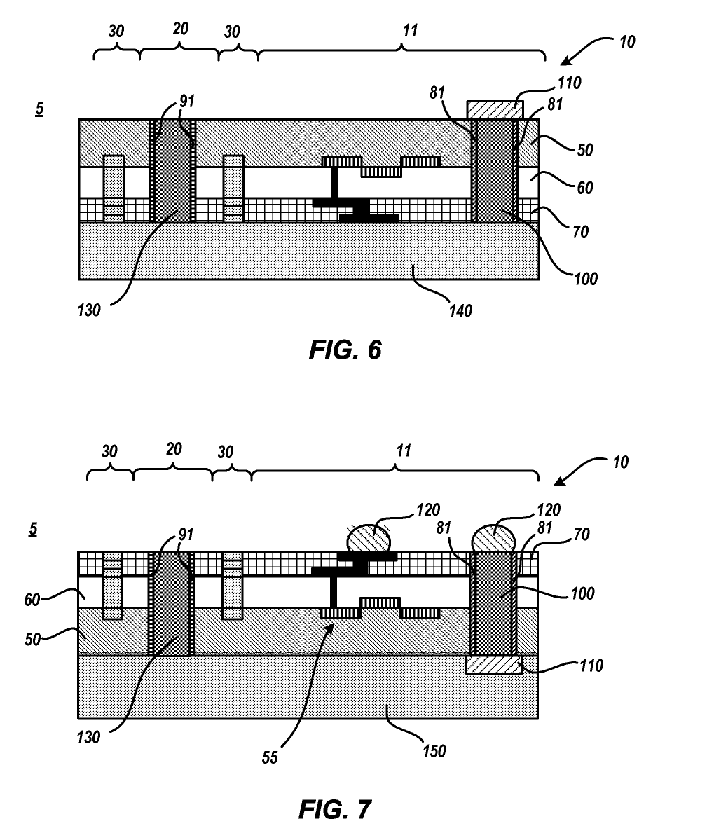

FIG. 6 depicts a cross section view of a semiconductor structure at intermediate stages of semiconductor device fabrication, in accordance with various embodiments of the present invention. At this stage of at this stage of wafer 5 fabrication, a handle 140 attached to the front side of wafer, the backside of wafer 5 is planarized and a backside contact 110 is formed. A handle 140 may be attached to wafer 5 and grinding or other chemical mechanical polishing (CMP) process may be performed on the backside substrate 50, until TSV 100 and/or TKV 130 are exposed. In this manner, TSV 100 and/or TKV 130 passes completely through chip 10 (e.g. TSV 100 and/or TKV 130 pass through substrate 50, BEOL wiring layer 70, FEOL layer 60).

Backside contact 110 may be an electrically conductive pad, ball, etc. electrically coupled to TSV 100. Contact 110 may be fabricated by forming a pad opening in a deposited dielectric layer, forming a seed layer, performing an electrochemical plating (ECP) to fill the opening with a metallic material, and then performing a CMP to remove excess metallic material. Additional metal layers and bumps (not shown) may also be formed on the backside contact 110, and electrically coupled to TSV 100. Unless otherwise indicated, generally, contact 110 may be formed by deposition techniques without deviating from the sprit of the embodiments herein claimed.

FIG. 7 depicts a cross section view of a semiconductor structure at intermediate stages of semiconductor device fabrication, in accordance with various embodiments of the present invention. At this stage of at this stage of wafer 5 fabrication, handle 140 is removed, handle 150 is attached, and one or more front side contacts 120 may be formed. A front side contact 120 may be an electrically conductive pad, ball, etc. electrically coupled to TSV 100 or device 55 (e.g., via wiring 75, contact 65, etc.) and may be fabricated by forming one or more pad openings in a deposited dielectric layer, forming a seed layer, performing an ECP to fill the opening with a metallic material, and then performing a CMP to remove excess metallic material. Unless otherwise indicated, generally, contact 120 may be formed by deposition techniques without deviating from the sprit of the embodiments herein claimed.

As shown in FIG. 7, TSV 100 and TKV 130 pass completely through chip 10. For example, TSV 100 passes through substrate 50, BEOL wiring layer 70, FEOL layer 60 whereas TKV 130 passes through the entire kerf region 20. In certain embodiments, TKV 130 is not electrically coupled to a front side contact 120 nor backside contact 110.

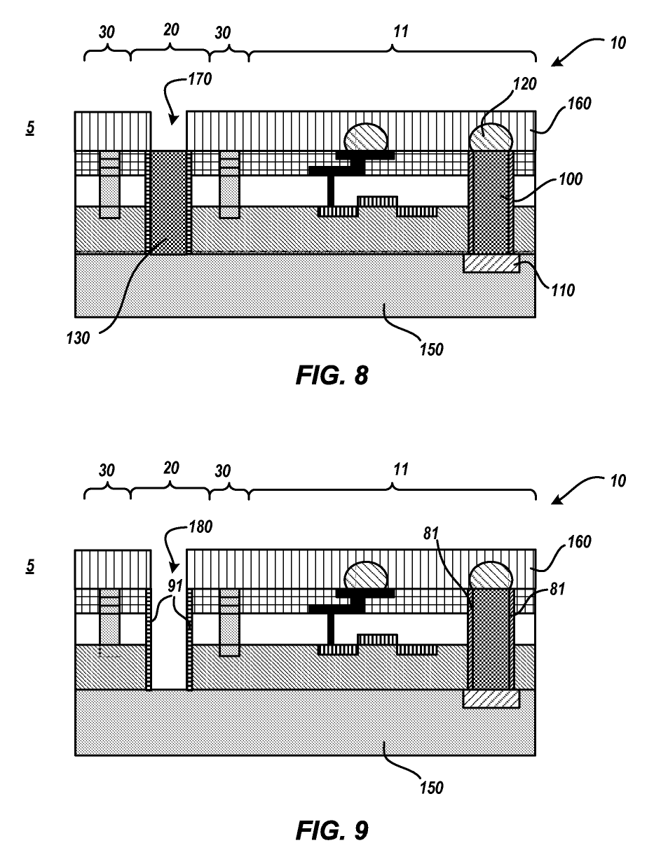

FIG. 8 depicts a cross section view of a semiconductor structure at intermediate stages of semiconductor device fabrication, in accordance with various embodiments of the present invention. At this stage of at this stage of wafer 5 fabrication mask 160 is formed and TKV 130 is exposed by TKV trench 170. Mask 160 generally is a protection layer formed to a thickness to cover front side contact(s) 120. TKV trench 170 may be formed, for example, utilizing photolithography and a wet etch, dry etch, or combination. More specifically, a pattern may be produced by applying masking layer such as a photoresist or photoresist with an underlying hardmask (e.g., mask 160, etc.), to the surface to be etched; exposing the photoresist to a pattern of radiation; and then developing the pattern into the photoresist utilizing a resist developer. Once the patterning of the photoresist is completed, the sections covered by the photoresist are protected while the exposed regions are removed using a selective etching process that removes the unprotected regions. In other embodiments, a laser may be utilized to form trench 170. Unless otherwise indicated, generally, trench 170 may be formed by other material 160 removal techniques without deviating from the sprit of the embodiments herein claimed.

FIG. 9 depicts a cross section view of a semiconductor structure at intermediate stages of semiconductor device fabrication, in accordance with various embodiments of the present invention. At this stage of at this stage of wafer 5 fabrication TKV 130 is removed forming separation trench 180.

Separation trench 180 may be formed, for example, utilizing photolithography and a wet etch, dry etch, or combination. More specifically, a pattern may be produced by applying masking layer such as a photoresist or photoresist with an underlying hardmask, to the surface to be etched; exposing the photoresist to a pattern of radiation; and then developing the pattern into the photoresist utilizing a resist developer. Once the patterning of the photoresist is completed, the sections covered by the photoresist are protected while TKV 130 is removed using a selective etching process that removes the TKV 130 while retaining the materials of e.g., liner 91. Separation trench 180 extends the entire thickness of chip 10, thereby separating neighboring chips 10 upon wafer 5. In certain embodiments, the removal of TKV 130 may be integrated with the removal processes utilized to form the trench 170. In other embodiments, a separate removal technique or process may be utilized. Unless otherwise indicated, generally, trench 180 may be formed by other TKV 130 material removal techniques without deviating from the spirit of the embodiments herein claimed.

Generally, the placement of TKV 130 is customizable to effectively form perimeters of each chip 10 upon wafer 5. Therefore, TKV 130 may be formed around the perimeter of variable sized, differing shaped, etc. chips 10 upon wafer 5. For example, one or more chips 10 upon wafer 5 may be square, rectangular, or irregularly shaped relative to other chips 10 upon wafer 5. Further, the width of TKV 130 may be less than current kerfs. Therefore, a greater number of chips 10 upon wafer 5 may be realized. In certain embodiments, TKV 130 may effectively become the kerf area wherein neighboring chips 10 are separated by only TKV 130. In other words, in utilizing embodiments of the present invention, crack stop region 30 becomes optional.

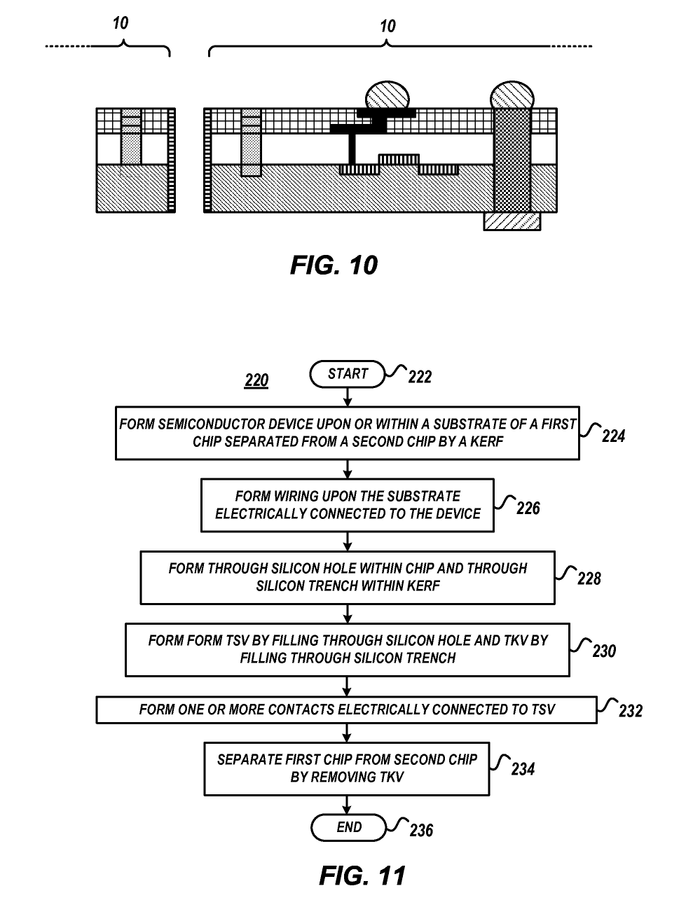

FIG. 10 depicts a cross section view of a semiconductor structure at intermediate stages of semiconductor device fabrication, in accordance with various embodiments of the present invention. At this stage of at this stage of wafer 5 fabrication handle 150 is removed and chips 10 are separated relative thereto.

FIG. 11 depicts an exemplary semiconductor device fabrication process flow method 220, in accordance with various embodiments of the present invention. Method 220 begins at block 222 by forming one or more semiconductor device(s) 55 upon or within a semiconductor substrate 50 within an active region 11 of a first chip 10 separated from a second chip 10 by kerf 20 (block 224). The first chip 10 and second chip 10 may be included within a wafer 5 separated from other surrounding chips 10 by kerf 20. In an embodiment, the first chip 10 and second chip 10 have similar perimeter shapes and/or dimensions. In other embodiments, the first chip 10 and second chip 10 have dissimilar perimeter shapes and/or dissimilar dimensions. In some embodiments, one or more chips 10 may also include a crack stop region 30 adjacent to and separating the active region 11 from the kerf 20.

Method 220 may continue by forming wiring 75 upon substrate 50 electrically coupled to devices 55 (block 226). Method 220 may continue by forming trough silicon hole 80 within the active region 11 of chip 10 and through silicon trench 90 within kerf region 20 (block 228). In some embodiments, trough silicon hole 80 and through silicon trench 90 may be formed simultaneously (i.e. during similar trench formation processes, etc.). In other embodiments, through silicon trench 90 may be formed in distinct trench formation processes, e.g. subsequent to fabricating active region 11 of chip 10. In embodiments, a liner 91 may be formed with trench 90 and/or a liner 81 may be formed within hole 80.

FIG. 11 depicts an exemplary semiconductor device fabrication process flow method 220, in accordance with various embodiments of the present invention. Method 220 begins at block 222 by forming one or more semiconductor device(s) 55 upon or within a semiconductor substrate 50 within an active region 11 of a first chip 10 separated from a second chip 10 by kerf 20 (block 224). The first chip 10 and second chip 10 may be included within a wafer 5 separated from other surrounding chips 10 by kerf 20. In an embodiment, the first chip 10 and second chip 10 have similar perimeter shapes and/or dimensions. In other embodiments, the first chip 10 and second chip 10 have dissimilar perimeter shapes and/or dissimilar dimensions. In some embodiments, one or more chips 10 may also include a crack stop region 30 adjacent to and separating the active region 11 from the kerf 20.

Method 220 may continue by forming wiring 75 upon substrate 50 electrically coupled to devices 55 (block 226). Method 220 may continue by forming trough silicon hole 80 within the active region 11 of chip 10 and through silicon trench 90 within kerf region 20 (block 228). In some embodiments, trough silicon hole 80 and through silicon trench 90 may be formed simultaneously (i.e. during similar trench formation processes, etc.). In other embodiments, through silicon trench 90 may be formed in distinct trench formation processes, e.g. subsequent to fabricating active region 11 of chip 10. In embodiments, a liner 91 may be formed with trench 90 and/or a liner 81 may be formed within hole 80.

Method 220 may continue by forming TSV 100 by filling trough silicon hole 80 with electrically conductive material and by forming and forming TKV 130 by filling through silicon trench 90 with a material that may be removed (block 230). In certain embodiments, an electrically insulating layer 81 is formed adjacent to the walls of trough silicon hole 80 prior to filling the trough silicon hole 80 with electrically conductive material. In certain embodiments, an electrically insulating layer 91 is formed adjacent to the walls of trough silicon trench 90 prior to filling the trough silicon trench 90 with TKV material.

TKV 130 may be fabricated by filling the internal space of the through-silicon trench 90 with a material that may be selectively removed in relation to the material of substrate 50, material of FEOL layer 60 formed upon substrate 50, and material of BEOL layer 70, formed upon FEOL layer 60. In embodiments, where liner 91 is utilized, TKV 130 may be fabricated by filling the internal space of the through-silicon trench 90 with a material that may be selectively removed in relation to the material of liner 91, substrate 50, material of FEOL layer 60 formed upon substrate 50, and material of BEOL layer 70, formed upon FEOL layer 60. The material of TKV 130 may be electrically conductive, a dielectric, etc. In some embodiments, TSV 100 and TKV 130 may be formed simultaneously (i.e. during similar trench formation processes, etc.). In other embodiments, TKV 130 may be formed in distinct trench formation processes, e.g. subsequent to fabricating active region 11 of chip 10.

Method 220 may continue by forming one or more contacts 110, 120 on the front side or backside of chip 10, respectively, electrically coupled to TSV 100 (block 232). In other words, in certain embodiments, TKV 130 is not electrically coupled to contacts 110, 120, etc. Method 220 may continue with separating and removing the first chip 10 and second chip 10 from wafer 5 removing the TKV 130 (block 234). In various embodiments, of the present invention, TKV 130 passes through the entire kerf region 20. Method 220 ends at block 236.

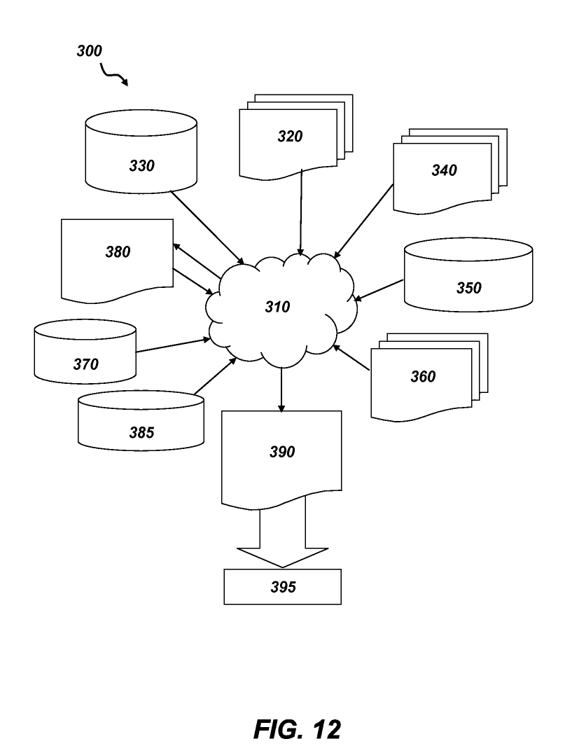

Referring now to FIG. 12, a block diagram of an exemplary design flow 300 used for example, in semiconductor integrated circuit (IC) logic design, simulation, test, layout, and/or manufacture is shown. Design flow 300 includes processes, machines and/or mechanisms for processing design structures or devices to generate logically or otherwise functionally equivalent representations of the structures and/or devices described above and shown in FIGS. 1-10.

The design structures processed and/or generated by design flow 300 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 300 may vary depending on the type of representation being designed. For example, a design flow 300 for building an application specific IC (ASIC) may differ from a design flow 300 for designing a standard component or from a design flow 300 for instantiating the design into a programmable array, for example a programmable gate array (PGA) or a field programmable gate array (FPGA) offered by Altera® Inc. or Xilinx® Inc.

FIG. 12 illustrates multiple such design structures including an input design structure 320 that is preferably processed by a design process 310. Design structure 320 may be a logical simulation design structure generated and processed by design process 310 to produce a logically equivalent functional representation of a hardware device. Design structure 320 may also or alternatively comprise data and/or program instructions that when processed by design process 310, generate a functional representation of the physical structure of a hardware device. Whether representing functional and/or structural design features, design structure 320 may be generated using electronic computer-aided design (ECAD) such as implemented by a core developer/designer.

When encoded on a machine-readable data transmission, gate array, or storage medium, design structure 320 may be accessed and processed by one or more hardware and/or software modules within design process 310 to simulate or otherwise functionally represent an electronic component, circuit, electronic or logic module, apparatus, device, structure, or system such as those shown in FIGS. 1-10. As such, design structure 320 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 310 preferably employs and incorporates hardware and/or software modules for synthesizing, translating, or otherwise processing a design/simulation functional equivalent of the components, circuits, devices, or structures shown FIGS. 1-10. to generate a Netlist 380 which may contain design structures such as design structure 320. Netlist 380 may comprise, for example, compiled or otherwise processed data structures representing a list of wires, discrete components, logic gates, control circuits, I/O devices, models, etc. that describes the connections to other elements and circuits in an integrated circuit design. Netlist 380 may be synthesized using an iterative process in which netlist 380 is resynthesized one or more times depending on design specifications and parameters for the device. As with other design structure types described herein, netlist 380 may be recorded on a machine-readable data storage medium or programmed into a programmable gate array. The storage medium may be a non-volatile storage medium such as a magnetic or optical disk drive, a programmable gate array, a compact flash, or other flash memory. Additionally, or in the alternative, the storage medium may be a system or cache memory, buffer space, or electrically or optically conductive devices in which data packets may be intermediately stored.

Design process 310 may include hardware and software modules for processing a variety of input data structure types including Netlist 380. Such data structure types may reside, for example, within library elements 330 and include a set of commonly used elements, circuits, and devices, including models, layouts, and symbolic representations, for a given manufacturing technology (e.g., different technology nodes, 14, 32 nm, 45 nm, 90 nm, etc.). The data structure types may further include design specifications 340, characterization data 350, verification data 360, design rules 370, and test data files 385 which may include input test patterns, output test results, and other testing information. Design process 310 may further include, for example, standard mechanical design processes such as stress analysis, thermal analysis, mechanical event simulation, process simulation for operations such as casting, molding, and die press forming, etc.

One of ordinary skill in the art of mechanical design can appreciate the extent of possible mechanical design tools and applications used in design process 310 without deviating from the scope and spirit of the invention claimed herein. Design process 310 may also include modules for performing standard circuit design processes such as timing analysis, verification, design rule checking, place and route operations, etc.

Design process 310 employs and incorporates logic and physical design tools such as HDL compilers and simulation model build tools to process design structure 320 together with some or all of the depicted supporting data structures along with any additional mechanical design or data (if applicable), to generate a second design structure 390. Design structure 390 resides on a storage medium or programmable gate array in a data format used for the exchange of data of mechanical devices and structures (e.g. information stored in a IGES, DXF, Parasolid XT, JT, DRG, or any other suitable format for storing or rendering such mechanical design structures).

Similar to design structure 320, design structure 390 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 1-10. In one embodiment, design structure 390 may comprise a compiled, executable HDL simulation model that functionally simulates the devices shown in FIGS. 1-10.

Design structure 390 may also employ a data format used for the exchange of layout data of integrated circuits and/or symbolic data format (e.g. information stored in a GDSII (GDS2), GL1, OASIS, map files, or any other suitable format for storing such design data structures). Design structure 390 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 1-10. Design structure 390 may then proceed to a stage 395 where, for example, design structure 390: proceeds to tape-out, is released to manufacturing, is released to a mask house, is sent to another design house, is sent back to the customer, etc.

The accompanying figures and this description depicted and described embodiments of the present invention, and features and components thereof. Those skilled in the art will appreciate that any particular nomenclature used in this description was merely for convenience, and thus the invention should not be limited by the specific process identified and/or implied by such nomenclature. Therefore, it is desired that the embodiments described herein be considered in all respects as illustrative, not restrictive, and that reference be made to the appended claims for determining the scope of the invention.

The exemplary methods and techniques described herein may be used in the fabrication of integrated circuit chips. The resulting integrated circuit chips can be distributed by the fabricator in raw wafer form (i.e., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). The chip is then integrated with other chips, discrete circuit elements and/or other signal processing devices as part of either (a) an intermediate product, such as a motherboard, or (b) an end product. The end product can be any product that includes integrated circuit chips, ranging from toys and other low-end applications to advanced computer products having numerous components, such as a display, a keyboard or other input device and/or a central processor, as non-limiting examples.

References herein to terms such as “vertical”, “horizontal”, etc. are made by way of example, and not by way of limitation, to establish a frame of reference. The term “horizontal” as used herein is defined as a plane parallel to the conventional plane or surface of the substrate, regardless of the actual spatial orientation of the semiconductor substrate. The term “vertical” refers to a direction perpendicular to the horizontal, as just defined. Terms, such as “on”, “above”, “below”, “side” (as in “sidewall”), “higher”, “lower”, “over”, “beneath” and “under”, are defined with respect to the horizontal plane. It is understood that various other frames of reference may be employed for describing the present invention without departing from the spirit and scope of the present invention.

The invention claimed is:

1. A semiconductor device comprising:
an active inner region comprising: a semiconductor substrate; an integrated circuit (IC) device layer formed upon the semiconductor substrate, the IC device layer comprising an integrated circuit device; a wiring layer formed upon the IC device layer, the wiring layer comprising wiring making electrical contact with the integrated circuit device, and;
a kerf region at the perimeter of the active inner region comprising a through kerf via (TKV) extending through the kerf region.

2. The semiconductor device of claim 1, further comprising a crack stop separating the active inner region and the kerf region.

3. The semiconductor device of claim 1, further comprising,
a through semiconductor via (TSV) extending through the substrate, the IC device layer, and the wiring layer.

4. The semiconductor device of claim 3, further comprising,
a first contact pad in electrical contact with an lower surface of the TSV and a second contact pad in electrical contact with an upper surface of the TSV.

5. The semiconductor device of claim 1, wherein the active inner region further comprises:
insulating film electrically isolating the TSV from the substrate, the IC device layer, and the wiring layer.

6. The semiconductor device of claim 1, wherein material of the TKV is selectively removable relative to a TKV liner.

7. The semiconductor device of claim 3, wherein the TKV and the TSV are similar materials.

8. The semiconductor device of claim 3, wherein the TKV and the TSV have similar widths.

9. A wafer comprising:
a plurality of chips, each comprising an active inner region that comprises a semiconductor substrate; an integrated circuit (IC) device layer formed upon the semiconductor substrate, the IC device layer comprising an integrated circuit device; a wiring layer formed upon the IC device layer, the wiring layer comprising wiring making electrical contact with the integrated circuit device, and;
a kerf that separates the plurality of chips comprising a through kerf via (TKV).

10. The wafer of claim 9 further comprising:
a crack stop region separating each chip from the kerf region.

11. The wafer of claim 9, wherein each chip further comprises:
a through semiconductor via (TSV) extending through the substrate, the IC device layer, and the wiring layer.

12. The wafer of claim 11, wherein each chip further comprises:
a first contact pad in electrical contact with an lower surface of the TSV and a second contact pad in electrical contact with an upper surface of the TSV.

13. The wafer of claim 11, wherein each chip further comprises:
insulating film electrically isolating the TSV from the substrate, the IC device layer, and the wiring layer.

14. The wafer of claim 9, wherein material of the TKV is selectively removable relative to a TKV liner.

15. The wafer of claim 11, wherein the TKV and the TSV are similar materials.

16. The wafer of claim 11, wherein the TKV and the TSV have similar widths.

17. A semiconductor structure fabrication method comprising:
forming a semiconductor device upon or within a substrate of a first integrated circuit (IC) chip separated from a second IC chip by a kerf region;
forming a through kerf via (TKV) extending through the kerf region, and;
separating the first IC chip from the second IC chip by removing the TKV.

18. The semiconductor structure fabrication method of claim 17, wherein the first IC chip has a similar geometry to the second IC chip.

19. The semiconductor structure fabrication method of claim 17, wherein the first IC chip has a dissimilar geometry to the second IC chip.

20. The semiconductor structure fabrication method of claim 17, further comprising:
forming respective barrier liners about the perimeter of the first IC chip and second IC.
